(19) United States
(12) Patent Application Publication
(10) Pub. No.: US 2024/0295729 A1
(43) Pub. Date: Sep. 5, 2024

(54) Actuating Device

(71) Applicant: SINTEF TTO AS, Trondheim (NO)

(72) Inventors: Zeljko Skokic, Trondheim (NO); Jo Gjessing, Trondheim (NO); Tobias Dahl, Trondheim (NO)

(21) Appl. No.: 18/276,589

(22) PCT Filed: Feb. 10, 2022
(86) PCT No.: PCT/GB2022/050363

§ 371 Date: Aug. 9, 2023

(30) Foreign Application Priority Data
Feb. 10, 2021 (GB) 2101833.8

(51) Int. Cl. G02B 26/08; H10N 30/20

(52) U.S. Cl. CPC G02B 26/0858; H10N 30/2044; H10N 30/2047

(57) ABSTRACT

An actuating device and projection and imaging systems using said actuating device are provided. The actuating device includes at least one actuator arm having a piezoelectric membrane. The actuator arm has a width at least ten times its thickness. The actuating device also includes a moveable element, connected to the actuator arm, such that actuation of the actuator arm causes movement of the moveable element.

### FIELD OF THE DISCLOSURE

This invention relates to piezoelectric actuating devices for use in a range of applications, particularly, but not exclusively for use in moveable mirror devices.

### BACKGROUND

It is known to apply voltages to actuate mechanical structures for enabling rotation and displacement of small-scale devices e.g. micro-mirrors. However, it is hard to achieve as large a deflection angle as would be desirable without applying high voltages or compromising the accuracy or robustness of the device.

Existing microelectromechanical systems (MEMS) scanning micro-mirrors operate by actuating attachments surrounding a central mirror. Typically, the actuators receive an AC current and oscillate either on one or two axes. In micro-mirror applications, the actuators may be driven by electromagnetic, electrostatic, thermo-electric or piezo-electric effects. Magnetically actuated micro-mirrors, which use the Lorentz force, are the most commonly used in industry due to their suitability for static and dynamic operation.

### SUMMARY

From a first aspect, the invention provides an actuating device comprising:
at least one actuator arm comprising a piezoelectric membrane and having a width at least ten times its thickness; and
a moveable element, connected to the actuator arm, such that actuation of the actuator arm causes movement of the moveable element.

Thus it will be seen that, in accordance with the invention, an actuating device is provided having a piezoelectric actuator arm in the form of a thin membrane. It will be appreciated by the skilled person that when the piezoelectric arm is actuated, i.e. a voltage is applied, an inverse piezoelectric effect results in a dimensional change and/or a deformation of the membrane. The movement caused by the dimensional and/or deformational change of the actuator arm causes the moveable element to move in a desired direction. Making the actuator arm in the form of a thin membrane, i.e. having a width at least ten times its thickness, may allow for a large movement, e.g. deflection, of the moveable element. The actuator arm having a width at least ten times its thickness enables the actuating device to be relatively stiff and robust whilst still providing relatively large deflections. In particular, it allows for the creation of robust actuating device designs which does not have weak points that would be easy to break during operation.

The actuator arm could be arranged so that piezoelectric deflection is provided throughout its length by application of a voltage thereto. In a set of embodiments however, the actuator arm comprises a plurality of independently addressable piezoelectric segments. This allows only part of the arm to be actuated by applying a voltage to one or more segments thereof whilst not applying a voltage to one or more other segments thereof. This may provide a greater degree of control over how the moveable element is moved. In a set of embodiments the individually addressable segments are contiguous. However this is not essential—e.g. they could be separated by one or more spacer portions which are not addressable (i.e. cannot be caused to deflect by application of a voltage).

In a set of embodiments the device comprises a gap between at least part of the actuator arm and the moveable element. In other words the actuator arm is only connected to the moveable element along part of its length. This ‘open’ membrane design may have a lower resonant frequency compared to a continuous membrane, and permit the membrane to deform more easily through torsion of the actuator arm, allowing for increased movement of the moveable element.

In a set of embodiments the device comprises a single actuator arm extending at least partially around a perimeter of the moveable element. In a set of embodiments, the actuator arm extends at least half-way around said perimeter of the moveable element—e.g. at least three quarters of the way around said perimeter of the moveable element. In a set of such embodiments the actuator arm extends around the perimeter of the moveable element with a uniform spacing except for the connection between them. In a preferable set of embodiments, the single actuator arm curves around the perimeter of the moveable element. This curved shape of the single actuator arm allows designs to be made which have no ‘weak spots’—i.e. spots at which the actuator arm could easily break. Known actuators often suffer from weak spots; typically occurring at the edges or corners at the distal ends of straight and narrow actuator arms. In such embodiments, because of the spiral shape of the actuator arms, the relatively long actuator arms allow for more deflection for the wide membrane.

Where, as is preferred, the single actuator arm comprises a plurality of individually addressable piezoelectric segments, the segments will typically be disposed at different locations around the perimeter and thus at different distances to the connection to the moveable element. Selective actuation of different segments or groups thereof may therefore provide different deflections of the moveable element.

In another set of embodiments the device comprises a plurality of actuator arms each connected to the moveable element; wherein each of the plurality of actuator arms can be actuated independently to move the moveable element.

In a set of embodiments, each arm comprises a plurality of individually addressable piezoelectric segments. By actuating one or more segments or groups thereof across the separate arms, a high degree of control and different types of movement of the moveable element may be achieved.

In a set of embodiments the actuator arms and segments thereof are arranged such that the moveable element is tilted by selectively actuating the segments on one side of the moveable element. For example, actuating all the segments adjacent to one half of the device may give maximum angular deflection even though there may be one or more segments that are closest to the side of the moveable element that is most displaced, that is/are not actuated.

In a set of embodiments the actuator arms and segments thereof are arranged such that the moveable element is translated vertically (i.e. in a direction normal to the plane of the piezoelectric membrane) by selectively actuating the segments either closest to or furthest from the moveable element respectively. This vertical translation motion may be thought of as a ‘piston’ motion, in contrast to the more typical tilt motion. This further opens up the possible applications of actuator devices in accordance with the invention. For example the moveable element may act like a diaphragm to generate acoustic waves. In such embodiments the moveable element would not typically be optically reflective (although of course such a possibility is not excluded).

In an exemplary set of embodiments, the device has only two actuator arms each extending at least partially around a respective portion of a perimeter of the moveable element. In a set of such embodiments, each actuator arm extends less than half-way around said perimeter of the moveable element—e.g. between a quarter and a half of the way around the perimeter of the moveable element. Such a device may a plane of symmetry (e.g. bisecting the centre of the moveable element wherein each of the two actuator arms are equidistant to the plane of symmetry). Both of the actuator arms may be independently addressable. Preferably, both actuator arms are arranged to receive the same voltage upon actuation (e.g. within 10%, within 20% or within 30%). Having a similar (e.g. the same) voltage applied to each of the two actuator arms may help allow for more symmetrical deflection.

In a set of such embodiments each actuator arm extends around the respective portion of the moveable element with a spacing symmetrical to the other actuator arm (e.g. a substantially uniform spacing).

In a set of such embodiments, the two actuator arms are connected to the moveable element via a common connection. In such embodiments actuating both actuator arms simultaneously may result in maximal angular deflection of a side of the moveable element closest to the common connection. In other words, the maximum physical displacement (e.g. lift) achieved occurs on the side of the actuating device that is the side connected to the moveable element. Symmetry of such an arrangement allows such maximal deflection to be achieved in two different directions. In contrast to single-armed embodiments, such two-armed arrangements (wherein each arm curves round a portion of an edge of the moveable element) may have a reduced inherent tendency to exhibit weak spots. In such embodiments, the shorter actuator arms can be very robust (owing to a greater stiffness) and although they may produce a smaller deflection of the moveable element than is produced by a single arm of comparable length, they may be well-suited to oscillating applications which take advantage of the high resonance frequency of the device.

In another exemplary set of embodiments the device comprises four actuator arms. Each of the four actuator arms may comprise two piezoelectric segments such that there are eight independently addressable segments in total. For example, each arm may comprise an inner segment proximal to the moveable element and an outer segment distal to the moveable element. In a set of such embodiments, the inner segment of each actuator arm is curved, e.g. through 90 degrees, and the outer segment of the actuator arm is straight. This may provide a ‘spiral’ arrangement of the actuator arms.

In such embodiments actuating segments disposed on one side of a line through the centre of the moveable element may result in maximal angular deflection of a side of the moveable element 90° around from the actuated segments—i.e. sides of the moveable element most displaced are at right angles to the aforementioned centre line. In other words, the maximum angular deflection achieved occurs on the side of the actuating device that is ‘next to’ the side being actuated. Symmetry of such an arrangement allows such maximal deflection to be achieved in four different directions. Similarly to the single-armed embodiment, this spiral arrangement (having a curved inner segment) of the actuator arms does not have any weak spots. In such embodiments, because of the spiral shape of the actuator arms, the relatively long actuator arms compensate for the resistance to torsion (owing to their stiffness) allowing for more deflection of the wide membrane—i.e. over the length of the actuator arm, it can accumulate enough torsion when actuated.

In such a set of embodiments, piston motion can be achieved by actuating only the outer segments to give the maximal positive vertical translation (i.e. upward deflection) and actuating only the inner segments to give the maximal negative vertical translation (i.e. downward deflection).

In a set of embodiments, the moveable element comprises an optically reflective surface—i.e. the moveable element comprises a mirror element so that the actuating device acts as a moveable mirror. The moveable element may, for example, be made from a suitable reflective material or comprise a reflective coating. Alternatively, a separate mirror element could be mounted to the moveable element.

The Applicant has found that a moveable mirror benefitting from the membrane actuator arm structure in accordance with the invention may be capable of increased angular movement in comparison with existing MEMS solutions—e.g. giving very high optical deflection angles of 25° to 30° for a 3 mm mirror in (quasi)static operation. An actuating device designed in accordance with the invention, having high deflection capability and thus a large field of view, could have applications in a wide variety of optical technologies.

In a set of embodiments the mirror element has an aperture size between 0.1 mm and 50 mm, e.g. between 0.5 mm and 10 mm—e.g. between 1 mm and 5 mm.

Moreover the Applicant has found that actuating devices in accordance with the invention can be used to give stable and accurate static deflection. This contrasts with existing moveable mirrors, e.g. MEMS mirrors, which typically operate in a resonant oscillating fashion and so are limited to applications involving scanning. Being able to operate an actuating device, e.g. a moveable mirror, in static mode expands the range of potential applications.

The moveable element may have any suitable shape. However, in a set of embodiments, the moveable element is circular. In another set of embodiments, the moveable element comprises an elliptical shape.

In a set of embodiments the or each actuator arm has a constant width along its length. However this is not essential. Where the width is not constant the minimum width is at least 10 times the thickness of the arm. The width or minimum width of the or each actuator arm may be between 10 and 1000 times its thickness—e.g. between 50 and 500 times its thickness—e.g. approximately 100 times its thickness.

In a set of embodiments, the moveable element has an area of between 0.005 mm² and 20 cm²—e.g. between 0.5 mm² and 20 mm².

In a set of embodiments the or each actuator arm is connected to the moveable element via a connecting member. The connecting member may be thicker than the actuator arm which may provide greater strength where the connection is relatively narrow. The moveable element could be integrally formed with actuator arm or fabricated as a separate component and attached to the actuator arm.

In a set of embodiments the mass per unit area of the moveable element is greater than that of the actuator arm(s). For example the moveable element could simply be thicker than the actuator arm or a separate mass could be attached to the moveable element, typically on the side opposite the outwardly facing surface of the moveable element in use. The greater mass per unit area of the moveable element may prevent the moveable element from being deformed upon actuation of the actuator arm, for example, by increasing the stiffness of the moveable element. The aforementioned connecting member may be of comparable thickness to the moveable element.

Where provided, the separate mass may be any suitable size or shape, however in a set of embodiments the mass comprises a cylindrical shape having a maximum width (e.g. diameter) equal to or greater than its thickness—e.g. at least twice its thickness—e.g. at least five times its thickness. The width of the mass may be the same as that of the moveable element.

In a set of embodiments, the moveable element comprises a plurality of individually addressable piezoelectric sections. Therefore, the moveable element may be a deformable moveable element which can change shape on actuation (e.g. the surface of the deformable moveable element may change curvature). Upon actuation there may be minimal (e.g. zero) lift around the perimeter of the deformable moveable element and maximal lift (e.g. of several hundred micrometres) at the centre of the deformable moveable element, thus giving a curved profile. The extent of this maximal lift may depend on the diameter of the moveable element—e.g. if a greater lift is desired, then a moveable element having a greater diameter can be selected. The deformable moveable element may be thicker or thinner than the actuator arm(s). For example, a deformable moveable element which is thicker than the actuator arms will provide a smaller maximal lift, however, a reduced flexibility may provide greater deflection of the moveable element (e.g. more degrees of freedom). In a set of embodiments, the deformable moveable element has a thickness equal to the actuator arm(s) or within 25%, e.g. within 10% of the thickness of the actuator arm(s). The deformable moveable element having a similar thickness to the actuator arm(s) may help to make the fabrication process of the actuating device simpler, therefore, resulting in lower manufacturing costs.

The deformable moveable element may comprise a first individually addressable piezoelectric section and a second individually addressable piezoelectric section. Each section may have any suitable shape. The deformable moveable element may comprise concentric sections. In a set of embodiments, the first section is circular and the second section is an annulus surrounding the first section (e.g. the first section and second section being concentric). Applying a voltage to just the first section of the deformable element may result in a curved (e.g. concave) deformation of the deformable element and applying a voltage to just the second section of the deformable element may result in the opposite (e.g. convex) deformation. Therefore, the deformable element, can be curved in both directions (e.g. in a convex or concave manner). There may be more concentrically arranged sections (e.g. further annuli) surrounding the first section. An advantage of this may be improved control of the shape of the lens, e.g. which may lead to better control of the focussing or defocussing of light (e.g. a laser beam).

In a set of embodiments, the deformable moveable element has an upper surface and a lower surface wherein both the upper surface and lower surface have an optically reflective surface (e.g. a mirrored coating). This allows the moveable element to act as a reversible mirror. As there is no need for a mass to keep the deformable moveable element stiff, the lower surface of the deformable moveable element may also be used. Therefore, the actuating device may be dual-sided (e.g. upon actuation, the upper surface may comprise a convex shape for focussing and the lower surface may comprise a concave shape for defocussing).

A deformable moveable element may provide an actuating device with not only a high deflection angle, but also the ability to focus and de-focus. Furthermore, when the deformable moveable element has a mirrored surface, the ability to focus and defocus light may remove the need for focussing optics, i.e. further reducing the overall size of the device.

In a set of embodiments, the actuating device comprises a substrate, e.g. a frame, to which the or each actuator arm is connected to provide an anchor for the movement generated—i.e. the movement of the moveable member is with respect to the substrate surrounding the piezoelectric membrane. The substrate may be formed integrally with the actuator arms(s) or formed separately and subsequently attached thereto.

The or each actuator arm may be connected to the substrate by at least one edge thereof. In one set of embodiments the or each actuator arm is connected to the substrate at least partially, and preferably completely, along one edge at its distal end (i.e. the end not connected to the moveable element). In another set of embodiments, the or each actuator arm is connected to the substrate partially along its outer edge.

Upon actuation of an actuator arm, the portion of the actuator arm that is not connected to the substrate is free to move—e.g. to lift—when a voltage is applied.

In a set of embodiments, the membrane comprises a first piezoelectric layer and a second layer. In a set of embodiments, the first layer is a piezoelectric layer and the second layer is a dielectric layer. The piezoelectric layer may comprise any suitable material that exhibits piezoelectricity. In a set of embodiments, the piezoelectric membrane comprises a perovskite material—e.g. lead zirconate titanate (PZT). The piezoelectric layer is not necessarily continuous and may only partially cover the actuator arm—e.g. at the segments.

As stated above, the width of the actuator arm is at least ten times its thickness. Similarly, in a set of embodiments, the width of the piezoelectric layer is at least ten times its thickness, e.g. at least 50 times its thickness. In a set of embodiments the piezoelectric layer is substantially the same width as the actuator arm, e.g. at least 90% of the width of the actuator arm. The skilled person will recognise that it may be difficult to achieve an identical width in practice. Having such a wide piezoelectric layer may provide a large deflection upon actuation of a similarly wide actuator arm. Having a wide actuator arm increases its stiffness, therefore, a relatively wide piezoelectric layer may compensate for the resistance to torsion caused by the stiffness of the actuator arm.

Typically the actuating device comprises control electronics configured to control the actuation of the actuator arm(s)—e.g. by selectively applying a voltage to one or more actuator arms or segments thereof.

In a set of embodiments the actuating device provides the moveable element with three degrees of freedom—e.g. tilt in both directions about two orthogonal axes and translation along a third mutually orthogonal.

When the actuating device is in an equilibrium state, i.e. when the actuator arms are not being actuated, at least one surface of the moveable element is preferably coplanar with the actuator arm(s).

The applicant has realised that there are a number of novel and inventive applications of actuating devices in accordance with the invention.

Thus when viewed from another aspect the invention provides a projection system comprising a projector and an actuating device as described hereinabove wherein the moveable element of the actuating device is optically reflective. For example, the projector may comprise an LED projector or a laser beam projector which pairs a laser beam source with a fast moving (e.g. oscillating) mirror. Such a projector system beneficially exploits the advantages which can be achieved using the actuating devices set out herein—e.g. the wide range of movement.

The projector and actuating device may be located within a common housing or they may be provided in separate housings.

When viewed from another aspect the invention provides an imaging system comprising a camera and an actuating device as described hereinabove wherein the moveable element of the actuating device is optically reflective. Similarly, such an imaging system beneficially exploits the advantages which can be achieved using the actuating devices set out herein—e.g. the wide range of movement. The imaging system may comprise a module for gesture detection. The camera and actuating device may be located within a common housing or they may be provided in separate housings.

When viewed from another aspect the invention provides an imaging and projecting system comprising an imaging system and projection system set out above. The imaging system and projection system may each comprise respective actuating devices or the they could share a common actuating device. This system may provide interactivity as a user may use gestures to interact with an output of the imaging and projecting system (e.g. a projected image) and the system may modify the output (the projected image) based on the gesture detected by the imaging system. The projection system and imaging system may be located within a common housing or they may be provided in separate housings.

In respective sets of embodiments of the three aspects outlined above, a plurality of cameras and/or projectors and/or actuating devices may be provided. This may, for example, allow a plurality of projections (e.g. images) to be displayed at different positions within a relatively large zone (e.g. anywhere within a room) with those positions determined by a corresponding actuating device. This may be achieved by using the actuating device, which is generally able to exhibit a relatively large range of movement (i.e. deflection) while still being robust and resistant to breakage. In this way, the resolution of a projected image need not be constant over the entire zone, but instead can be high only where it needs to be—in discrete areas where this suits a given application. This avoids having to ‘over-engineer’ the imaging system relative to areas which don't require high resolution and helps to enrich projections in areas where higher resolution is required. Corresponding benefits apply to the cameras of imaging systems—i.e. a given camera may ‘see’ with greater detail only an area of interest. Therefore, power consumption and overall cost can be reduced by using a plurality of cameras and/or projectors and/or actuating devices to generate a rich, high resolution image that has lower resolution in less used or unused areas.

Features of any aspect or embodiment described herein may, wherever appropriate, be applied to any other aspect or embodiment described herein. Where reference is made to different embodiments or sets of embodiments, it should be understood that these are not necessarily distinct but may overlap.

### BRIEF DESCRIPTION OF THE DRAWINGS

Certain embodiments of the invention will now be described, by way of example only, with reference to the accompanying drawings, in which:

FIG. 1 is a plan view of an actuating device in accordance with an embodiment of the invention;

FIG. 2 is perspective view of the actuating device of FIG. 1;

FIG. 3 shows the actuating device of FIGS. 1 and 2 from below;

FIGS. 4a-7a are views similar to FIG. 2 showing selective actuation of various groups of the segments of the actuator arm;

FIGS. 4b-7b are simulations showing movement of the device corresponding to the selective actuation shown in FIGS. 4a-7a;

FIG. 8 is a greyscale photograph of the actuating device of FIGS. 1-7 in operation;

FIG. 9 is a plan view of an actuating device in accordance with a second embodiment of the invention;

FIG. 10 is perspective view of the actuating device of FIG. 1;

FIG. 11 shows the actuating device of FIGS. 9 and 10 from below;

FIGS. 12a-17a are views similar to FIG. 2 showing selective actuation of various groups of the segments of the actuator arm;

FIGS. 12b-17b are simulations showing movement of the device corresponding to the selective actuation shown in FIGS. 12a-17a;

FIG. 18 is a greyscale photograph of the actuating device of FIGS. 9-17;

FIG. 19 is a greyscale photograph of a further embodiment of the invention;

FIG. 20 is a photograph of a further embodiment of the invention;

FIG. 21 is a schematic diagram showing exemplary control electronics for use in any embodiment of the invention;

FIG. 22 is a perspective view of an actuating device in accordance with another embodiment of the invention;

FIG. 23 is a view similar to FIG. 22 showing actuation of the actuator arms;

FIG. 24 shows a simulation showing movement of the device corresponding to the actuation shown in FIG. 23;

FIG. 25 is a plan view of a variant of the central moveable element of an actuating device in accordance with embodiments of the invention;

FIG. 26 is a perspective view of the central moveable element shown in FIG. 25;

FIG. 27 is a perspective view showing the central moveable element of FIG. 26 upon actuation;

FIG. 28 is a side view of the central moveable element shown in FIG. 27;

FIG. 29 shows how the curvature of a reflecting central moveable element changes how light is deflected;

FIG. 30 shows the actuating device in a projector system;

FIG. 31 shows an example of a projector system using actuating devices in accordance with embodiments of the present invention; and

FIG. 32 shows another example of a projector system using actuating devices in accordance with embodiments of the present invention.

### DETAILED DESCRIPTION

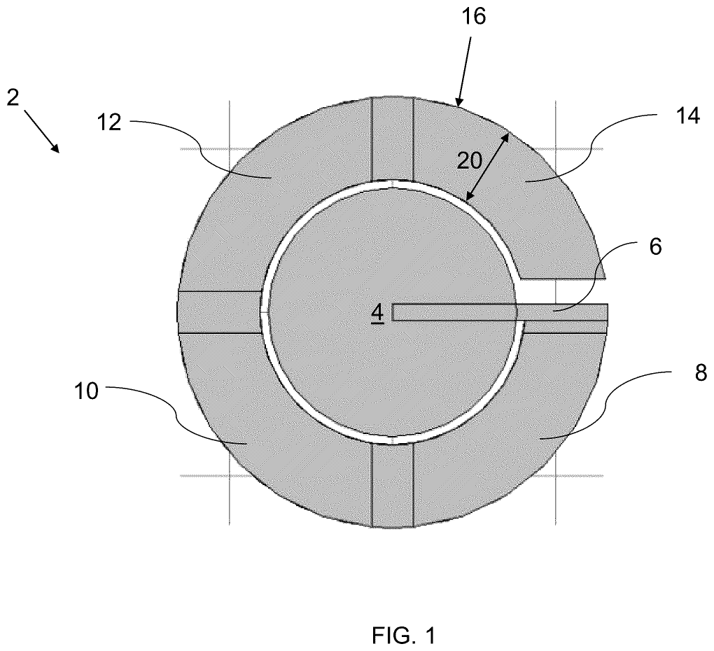

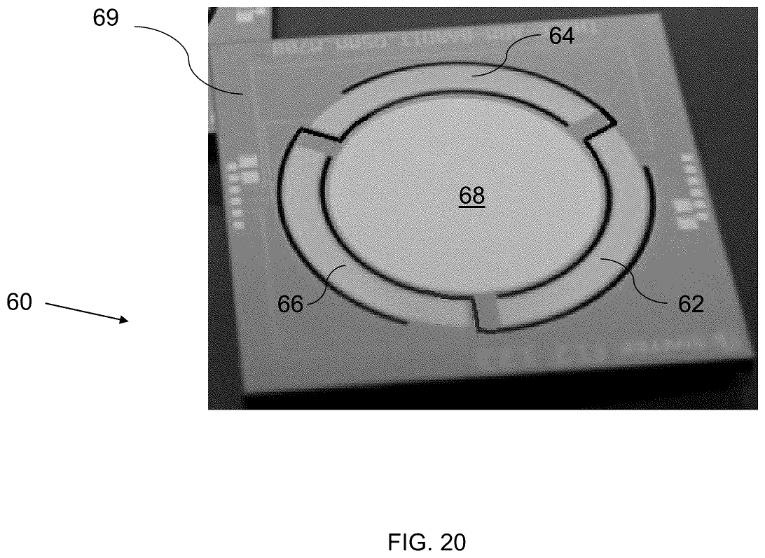

FIG. 1 shows a plan view of an actuating device 2 embodying the invention. In this example, the actuating device 2 is used as a moveable micromirror. The actuating device 2 has a single actuator arm 16 connected by a connecting beam 6 to a central moveable element 4. The actuator arm 16, moveable element 4 and connecting beam 6 are made primarily from silicon. The actuator arm 16 has four approximately equal—sized independently addressable segments 8, 10, 12, 14 where an additional layer of piezoelectric material—e.g. lead zirconate titanate (PZT) is provided. Each piezoelectric segment is connected to a respective control output of a corresponding control system (not shown but described below with reference to FIG. 21 in relation to the second embodiment).

The moveable element 4 has a reflective coating on top which provides the mirror element—i.e. for deflecting incident light to a desired position. The diameter of the mirror element is approximately 3 mm.

The width 20 of the actuator arm 16 is approximately one hundred times greater than its thickness (thickness being the dimension normal to the viewing plane). It thus has the form of a thin piezoelectric membrane in contrast for example to known piezoelectric torsion bars which are typically wire-like.

In this example, the overall size of the actuating device 2 is approximately 9 mm×9 mm. The C-shaped actuator arm 16 can be seen to curve closely around the moveable element 4 (i.e. the arm is as close as possible to the centre). This allows the moveable mirror to be as compact as possible, thus reducing the amount of space taken up by the device. This may be useful especially for inclusion in miniature devices—e.g. small wearables—where available space for additional components is scarce. However the design also allows the arm to be relatively long and thus to accumulate a significant degree of deflection along its length, despite being relatively stiff as a result of its significant width. Moreover the width of the arm allows for a wide junction region between the arm 16 and the central moveable element 4, thereby avoiding the thin weak spots prevalent in existing micro-mirror designs.

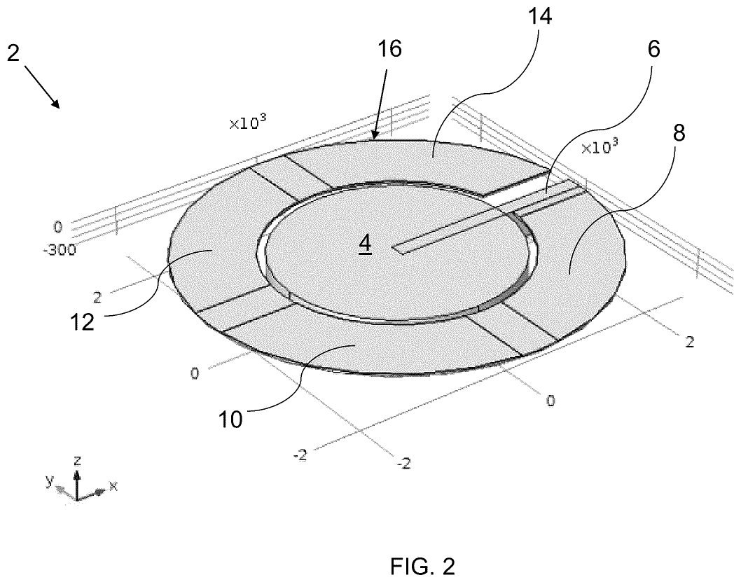

FIG. 2 shows a perspective view of the actuating device of FIG. 1. This view shows how the actuator arm 16 is thin relative to its width, having a width 20 two orders of magnitude greater than its thickness.

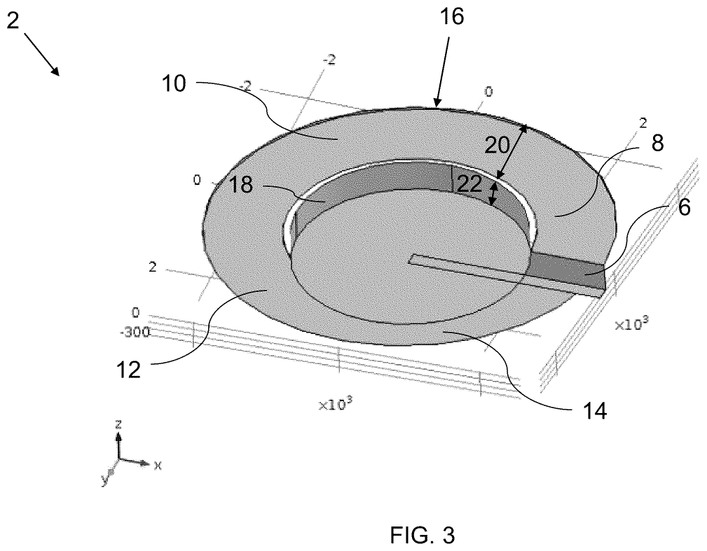

FIG. 3 shows a view of the actuating device 2 shown in FIGS. 1 and 2 from below. From here may be seen a mass 18 below the moveable element 4 which is integrally formed from silicon but could be fabricated separately and subsequently attached. The mass 18 has a thickness 22 at least ten times greater than the thickness of the actuator arm 16. The mass 18 helps to prevent the moveable element 4, and hence the mirror element from bending, keeping the mirror element flat while the actuator arm 16 bends.

The beam 6 connecting the actuator arm 16 to the moveable element 4 is cuboidal, and, in this example, has the same thickness 22 as the mass 18. The thickness of the beam 6 increases its stiffness such that it too stays rigid during actuation of the actuator arm 16.

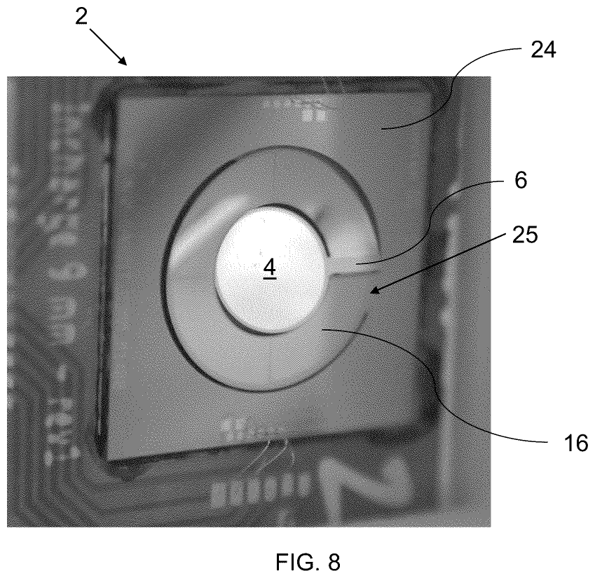

As can be seen in FIG. 8 which shows a greyscale photograph of the actuating device 2, the actuator arm 16 is integrally formed with a surrounding silicon substrate 24. The substrate 24 anchors the actuator arm 16 at the opposite end 25 thereof, away from the connection 6 to the central moveable element 4.

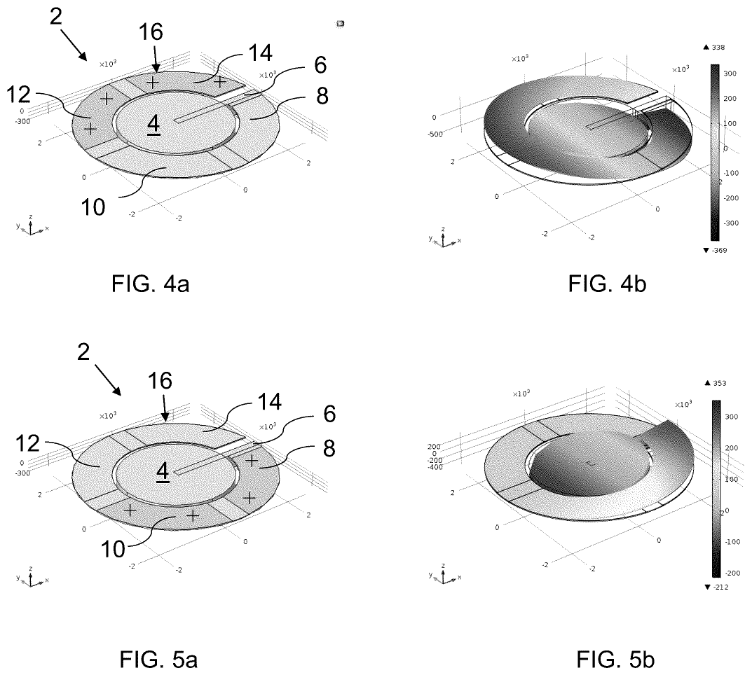

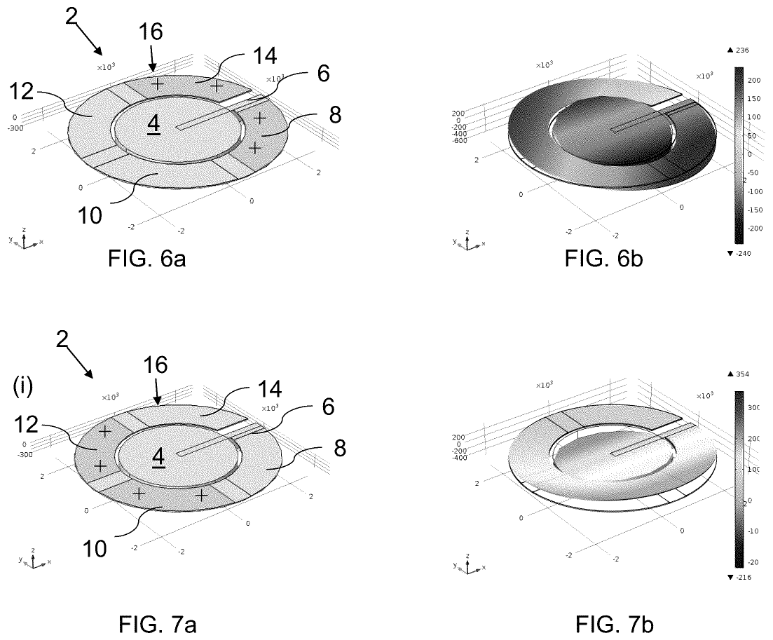

Operation of the first embodiment will now be described with reference to FIGS. 4a to 7a and 4b to 7b. A Cartesian coordinate basis is displayed in the bottom left corner of each of these Figures.

As previously mentioned, the four segments 8, 10, 12, 14 of the actuator arm 16 are independently addressable by a voltage controller. Depending on instructions sent from a processor, control electronics may select a subset (comprising one or more or even all) of the segments to receive a suitable voltage. The applied electric potential results in a dimensional change of the piezoelectric membrane formed by the arm 16. This is due to the inverse piezoelectric effect which is demonstrated by certain crystal or ceramic materials and allows a conversion of electrical energy to mechanical energy. The dimensional change caused by the applied electric potential results in a deformation of the actuator arm 16. As the actuator arm 16 is anchored to the substrate 24 this dimensional change results in a torsional deformation along the length of the arm 16.

To achieve the desired movement of the moveable element 4, a specific subset of segments must receive a voltage to actuate them. These specific subsets of actuable segments and their resulting deflection will be described below. In the drawings, the segments having a voltage applied thereto are indicated by the addition of ‘+’ signs on those segments.

FIG. 4a shows the actuating device 2 in a mode of operation where a voltage is applied to the two most distal segments 12, 14 of the actuator arm 16 (above the x-axis, where y is positive). Turning to FIG. 4b the resulting deflection (clockwise rotation about the y axis) of the actuator arm 16 and the moveable element 4 can be seen. Maximal lift occurs at the left-most edge of the actuator arm 16 and maximal drop occurs at the right-most edge of the arm. Hence, the most lift occurs at 90° to the side of the actuator arm that is subject to a voltage (i.e. the side that is actuated).

FIG. 5a shows the actuating device 2 in a mode of operation where a voltage is applied to the two adjacent segments 8, 10 nearest the end of the actuator arm 16 which is attached to the moveable element 4 (below the x-axis, where y is negative). FIG. 5b shows the device tilting the moveable element 4 in the opposite direction to FIG. 4b: about the y-axis (anticlockwise) with maximal lift of the actuator arm 16 at the right-most edge and maximal drop at the left-most edge.

FIG. 6a shows the actuating device 2 in a mode of operation where a voltage is applied to the two segments 8, 14 located either side of the connecting beam 6 (to the right of the y-axis, where x is positive). FIG. 6b shows the corresponding movement tilting the moveable element 4 about the x-axis.

FIG. 7a shows the actuating device 2 in a mode of operation where a voltage is applied to two adjacent segments 10, 12 located midway along the actuator arm 16 (to the left of the y-axis, where x is negative). FIG. 7b shows the resulting tilting of the moveable element 4 in the opposite direction to FIG. 6b, about the x-axis.

As can be seen in the one-armed micro-mirror described above, the moveable mirror element 4 is ‘hanging’ on one actuator arm which takes the form of a C-shaped piezoelectric membrane torsion beam. This torsion beam has the function of both providing lift and torsion upon actuation of pairs of the four segments 8, 10, 12, 14 so that by simply actuating two neighbouring segments, deflection in all four tilting directions is possible. Using only a single cantilever (actuator arm) with four independently actuable segments provides a micro-mirror which can rotate significantly without any weak spots. This provides a very robust device which can withstand deformation without breaking easily. The thin, membrane-form actuator arm enables significant torsion and allows the micro-mirror to rotate despite being wide and relatively stiff—this is because, over the length of the actuator arm, it can accumulate enough torsion. Looked at another way torsion resulting from the deformation of the piezoelectric membrane formed by the arm is ‘spread along’ the actuator arm 16 away from the anchored part of the arm, resulting in a large deflection without compromising the robustness of the device.

The actuating device 2 is implemented in these examples as a moveable mirror for non-resonant operation (e.g. for beam-steering). When a light beam is incident on the central mirror element 4, it can be reflected in a desired direction determined by the position and orientation of the moveable element 4 which is determined by which of the actuator segments are actuated.

FIG. 8 shows an example fabricated by the Applicant and energised in the way shown in FIG. 6a. Displacements of the edges of the moveable element 4 from equilibrium of up to approximately ±200 μm were achieved. This can provide an optical deflection angle of approximately 25-30 degrees which will be recognised to be very large compared to known static micro-mirrors.

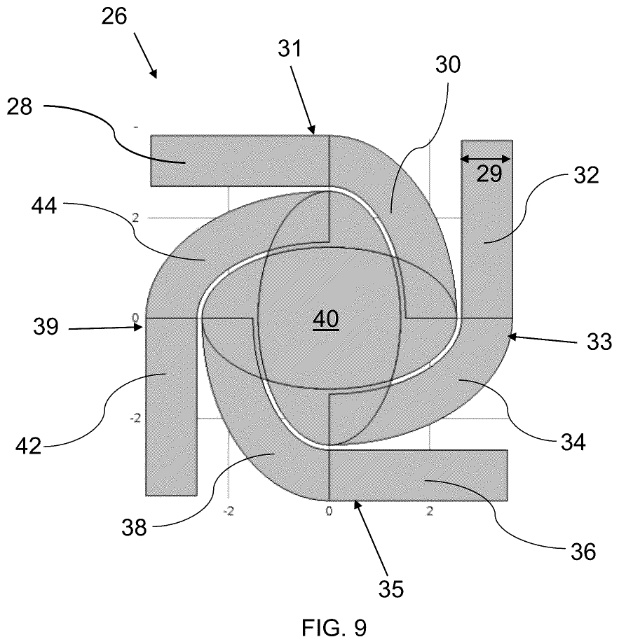

FIGS. 9 to 11 show another actuating device 26 embodying the invention. This embodiment has four actuator arms 31, 33, 35, 39 each having a width 29 two orders of magnitude greater than their thickness. The actuator arms 31, 33, 35, 39 are arranged in a spiral surrounding the central moveable element 40 which also has an optically reflective surface to make it a mirror element.

Each of the four actuator arms (e.g. 31) has two segments (e.g. 28, 30) and there are therefore eight segments 28, 30, 32, 34, 36, 38, 42, 44 in total. Similarly to the first embodiment, each segment 28, 30, 32, 34, 36, 38, 42, 44 is independently addressable by selectively applying a suitable voltage thereto. The four innermost segments 30, 34, 38, 44 of the actuator arms 31, 33, 35, 39 have a curved ribbon shape. The four outermost segments 28, 32, 36, 42 have a straight ribbon shape. The shape of the moveable element 40 comprises two overlapping ellipses disposed perpendicularly to each other, having a common centre. Each non-overlapping portion of the moveable element 40 comprises a connection to one of the actuator arms 31, 33, 35, 39.

As with the first embodiments the arms 31, 33, 35, 39 are relatively long and thus to accumulate a significant degree of deflection along their length, despite being relatively stiff as a result of its significant width. Moreover the width of the arms gives robust junction regions between them and the central moveable element 40.

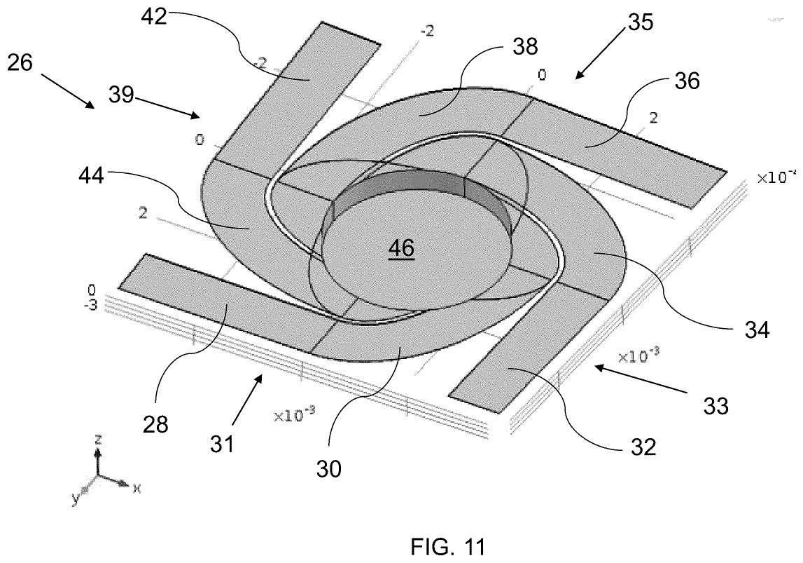

Similarly to the previous embodiment, a mass 46 (shown in FIG. 11) is disposed below the moveable element 40. This helps to prevent the moveable element 40 from deforming upon actuation of one or more of the actuator arms 31, 33, 35, 39 by increasing the stiffness of the moveable element 40. The mass 46 has a circular cross section, approximately coinciding with the overlapping portion of the two perpendicular ellipses. As before, the actuator arms 31, 33, 35, 39 are much thinner than their width by a factor of approximately one hundred.

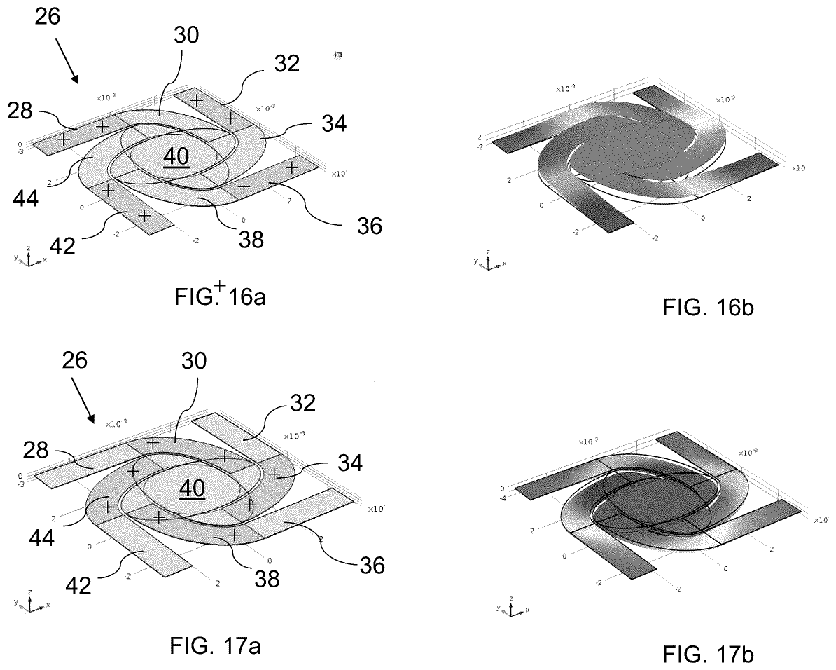

FIG. 18 shows how in practice the actuating device 26 comprises a silicon substrate 27. The substrate 27 anchors the distal ends of each of the four actuator arms 31, 33, 35, 39. The long edges of the actuator arms 31, 33, 35, 39 are not connected to the substrate 27—i.e. there is a gap either side of each actuator arm which allows the actuator arms to deform more freely resulting in the desired deflection of the moveable element 40. The optically reflective coating disposed on top of the moveable element 40 can be seen.

FIG. 21 shows a schematic circuit diagram for a control system for actuating the individual segments of the actuator arms of the micro-mirror device 26. Although this is shown in conjunction with only one of the mirror designs, a similar system can be used with any other design in accordance with the invention—e.g. the first embodiment (where only four control signals would be required).

A processor 106 is connected to control electronics 108 that are operable to control a voltage controller 110. The voltage controller 110 provides a DC voltage to the selected segments for static (non-resonant) operation.

The processor 106 sends instructions 114 to the control electronics 108, which in turn sends suitable commands 116 to the voltage controller 110. The system comprises eight individual connections 90, 92, 94, 96, 98, 100,102, 104 to the respective eight segments 28, 44, 42, 30, 38, 32, 34, 36. The voltage controller 110 may selectively apply a suitable voltage to one or more of the segments via these connections based on commands from the control electronics 108. A suitable voltage is applied to actuate the section based on the angle of deflection required. A range of suitable voltages for actuating the device may be between 0V and 20V. A greater applied voltage will generally result in a greater deflection of the moveable element. For an actuating device having a thicker piezoelectric layer (e.g. thicker piezoelectric films) higher voltages may be used; and with a thinner piezoelectric layer, lower voltages may be used.

As will be seen from the description below, the actuating device 26 in accordance with the second embodiment of the invention has three effective ‘degrees of freedom’—tilt about the x-axis, tilt about the y-axis, and displacement along the z-axis.

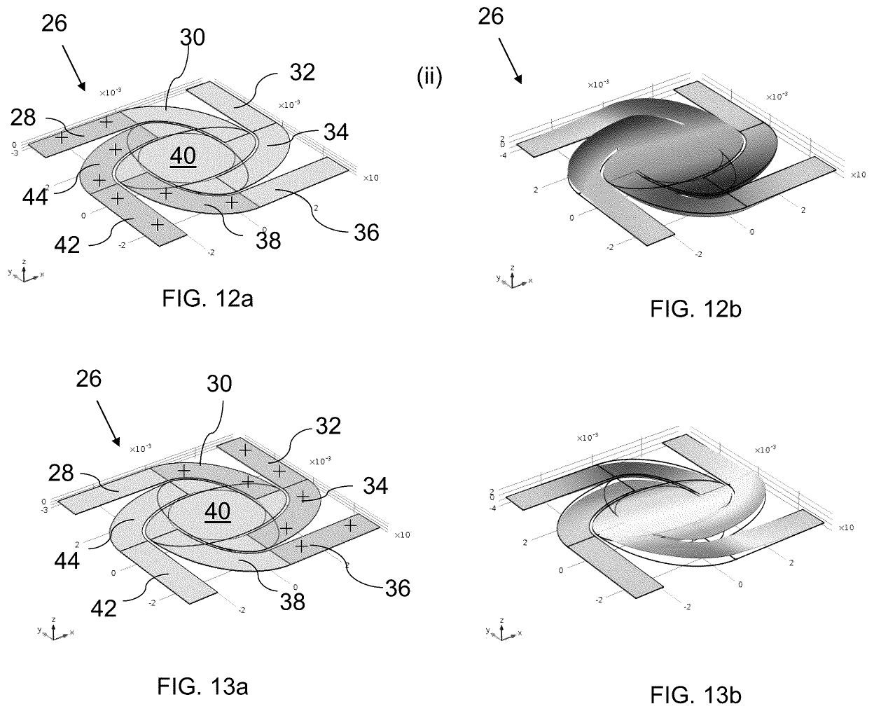

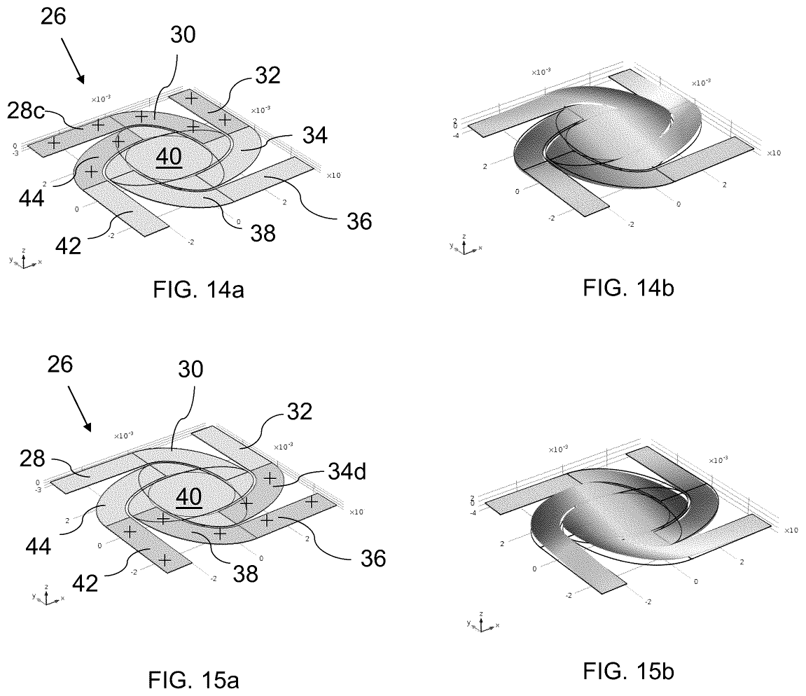

FIG. 12a shows the actuating device 26 in a mode of operation where a voltage is applied by the voltage controller 110 to the segments 28, 38, 42, 44 to the left of the y-axis (where x is negative). In other words, all the segments 28, 38, 42, 44 that are to the left of a line parallel to the y-axis passing through the centre of the moveable element 40 are actuated. Again, the ‘+’ signs indicate that a voltage is applied to those segments. FIG. 12b shows the resulting deflection of the actuator arms and the moveable element 40: rotation about the x axis. Similarly to the effect shown in the first embodiment, the most lift occurs at 90° to the side of the actuator arm that is subject to a voltage (i.e. the side that is actuated). In particular it may be noted that the segment 30 which is closest to the side of the moveable element 40 which is lifted most is not itself energised.

FIG. 13a shows the actuating device 26 in a mode of operation where a voltage is applied to the segments 30, 32, 34, 36 to the right of the y-axis (where x is negative). In other words, all the segments 30, 32, 34, 36 that are to the right of the previously mentioned centre line. FIG. 13b shows the moveable element 40 being tilted in the opposite direction to that shown in FIG. 13a as a result.

FIG. 14a shows the actuating device 26 in a mode of operation where a voltage is applied to the segments 28, 30, 32, 44 above the x-axis (where y is positive). In other words, all the segments 28, 30, 32, 44 that are above a line parallel to the x-axis and passing through the centre of the moveable element 40 are actuated. The result of actuating these segments is shown in FIG. 14b which shows the device tilting the moveable element 40 anticlockwise about the y-axis.

FIG. 15a shows the actuating device 26 in a mode of operation where a voltage is applied to the segments 34, 36, 38, 42 below the x-axis (where y is negative). In other words, all the segments 34, 36, 38, 42 that are below the above-mentioned line are actuated. FIG. 15b shows the resulting tilting of the moveable element 40 in the opposite direction to that shown in FIG. 14b, clockwise about the y-axis.

In addition to tilting about the x and y axes, the actuating device shown in FIGS. 9 to 11 has the capability to perform piston motion—i.e. translation in the z-direction. FIG. 16a shows how displacement in the positive z-direction is achieved (i.e. upwards piston motion). A voltage is applied by the controller 110 to the outermost (distal) segments 28, 32, 36, 42. As may be seen in FIG. 16b this provides upward translational displacement of the moveable element 40 without tilting.

FIG. 17a shows how displacement in the negative z-direction is achieved (i.e. downwards piston motion). Here a voltage is applied to the innermost segments 30, 34, 38, 44. Turning to FIG. 17b the downward displacement of the moveable element 40 resulting from this can be seen.

The piston motion shown in FIGS. 16 and 17 allows the actuating device to be used in certain acoustic applications where the moveable element acts as an acoustic diaphragm. For example, the actuating device may be used as a compact loudspeaker—e.g. for use in in-ear headphones or hearing aids etc. Clearly in such embodiments the moveable element may not have an optically reflective surface.

As mentioned above, FIG. 18 shows a greyscale photograph of an example of the actuating device 26 fabricated by the Applicant. It has been found that this can provide similar tilting movement the first embodiment and a displacement along the z-axis of up to ±200 μm when using the device in ‘piston’ mode.

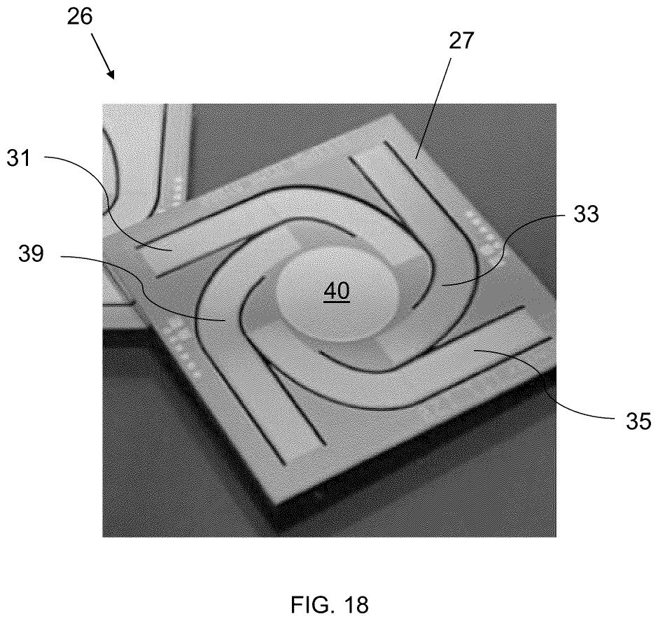

FIG. 19 shows a variation of the embodiment shown in FIG. 18. The device 50 shown in FIG. 19 also comprises four actuator arms 52, 54, 56, 58. However, instead of the actuator arms having a uniform width, each of the actuator arms diverges towards the distal end thereof. This design provides more of the area of the substrate 59 that is able to flex which may be beneficial in some applications.

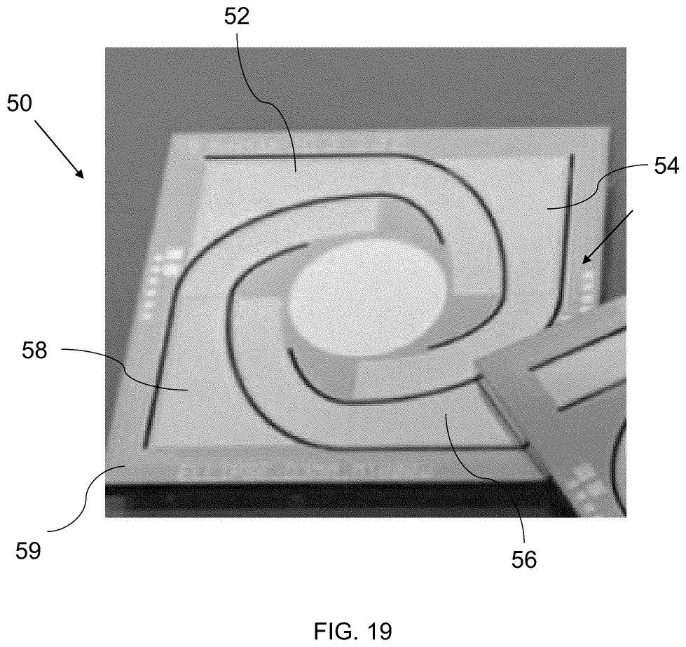

The invention is not limited to the one-armed and four-armed designs described above. For example, FIG. 20 shows a further actuating device 60 design embodying the invention similar to that of FIG. 8 but having three separate actuator arms 62, 64, 66 and a large central moveable element 68. Each of the actuator arms 62, 64, 66 is connected to the substrate 69 and may comprise one or a plurality of segments.

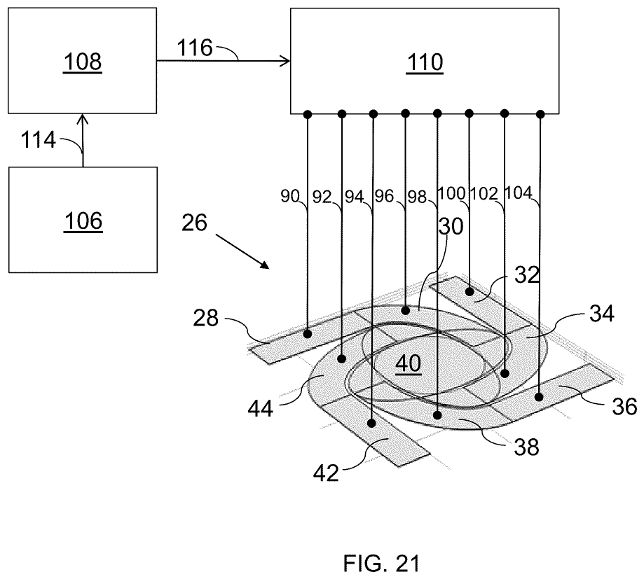

FIGS. 22 to 24 show another actuating device 300 embodying the invention. This embodiment has two actuator arms 302, 308 each having a width between one and three orders of magnitude greater than their thickness. The actuator arms 302, 308 are each arranged similarly to the arms of the single armed embodiments in FIGS. 1-8. Each actuator arm 302, 308 can be seen to curve closely around the moveable element in a semi-circular shape (e.g. a C-shape) with each actuator arm extending slightly less than 50% around the perimeter of the central moveable element 304.

The central moveable element 304 also has an optically reflective surface to make it a mirror element.

Each of the two actuator arms 302, 308 are addressable by applying a suitable voltage thereto which is preferably the same for each actuator arm. As with the first two embodiments the arms 302, 308 are relatively long, however, due to their shorter length they are relatively stiffer compared to the single armed embodiment shown in FIGS. 1-8.

Similarly to the first two embodiments at least, a mass 318 (shown in FIG. 22) is disposed below the moveable element 304. This helps to prevent the moveable element from deforming upon actuation of the actuator arms 302, 308 by increasing the stiffness of the moveable element 304. The mass 318 has a circular cross section, coinciding with the circular cross section of the moveable element 304.

FIG. 22 shows how each actuator arm 302, 308 is thin relative to its width, having a width two orders of magnitude greater than its thickness.

As with the first embodiment (of FIGS. 1-8) a cuboidal beam 306, having the same thickness as the mass 318, connects each actuator arm 302, 308 to the moveable element. Each actuator arm 302, 308 is connected to a substrate (not shown) at the opposite end thereof, away from the connection to the central moveable element 304 to provide anchorage.

There is a plane of symmetry 310 that extends through the centre of the moveable element 304 and the beam 306, equidistant from each arm 302, 308, which is shown by the dashed line 310 in FIG. 22.

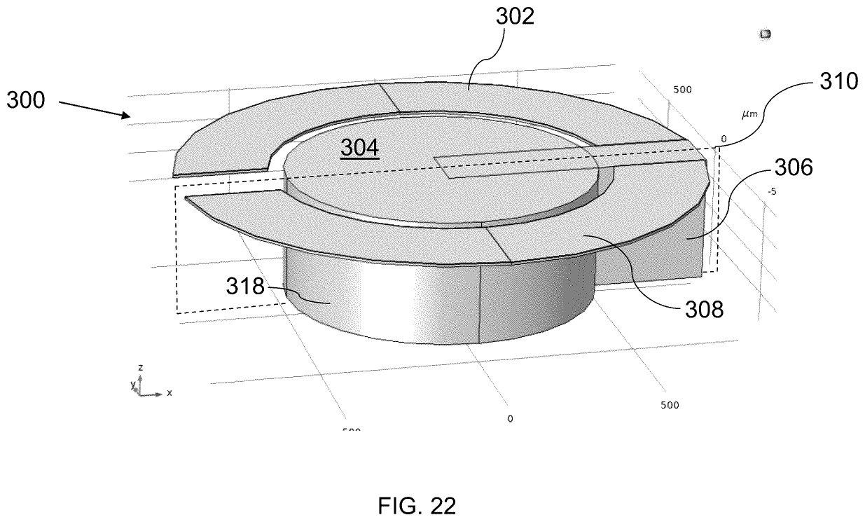

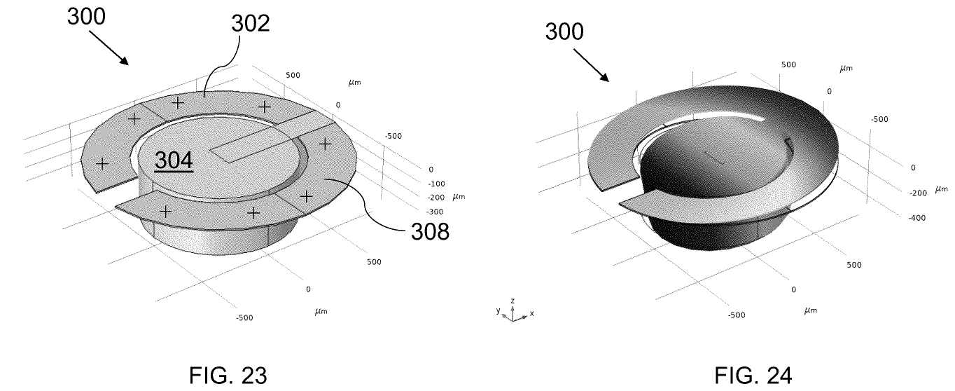

FIG. 23 shows the actuating device 300 in a mode of operation where a voltage is applied by the voltage controller to both arms 302, 308. Here, the ‘+’ signs indicate that a voltage is applied to those segments. FIG. 24 shows the resulting deflection of the actuator arms 302, 308 and the moveable element 304: rotation about the y axis. The most lift occurs at the side that is closest to the beam 306.

The two-armed actuating device 300 shown in FIGS. 22 to 24 has one degree of freedom—i.e. it can rotate about the y-axis. This makes it suitable for use as an oscillating or scanning mirror as it has a higher resonant frequency and therefore can move (rotate) fast compared to other designs. The relatively shorter arms, compared to other embodiments, give the actuating device 300 increased stiffness and a more robust design. As described above the two-armed actuating device 300 is symmetrical. The symmetry and stiffness of the actuating device 300 helps to keep the resting position of the actuating device 300 from drifting—i.e. the device 300 is self-centering.

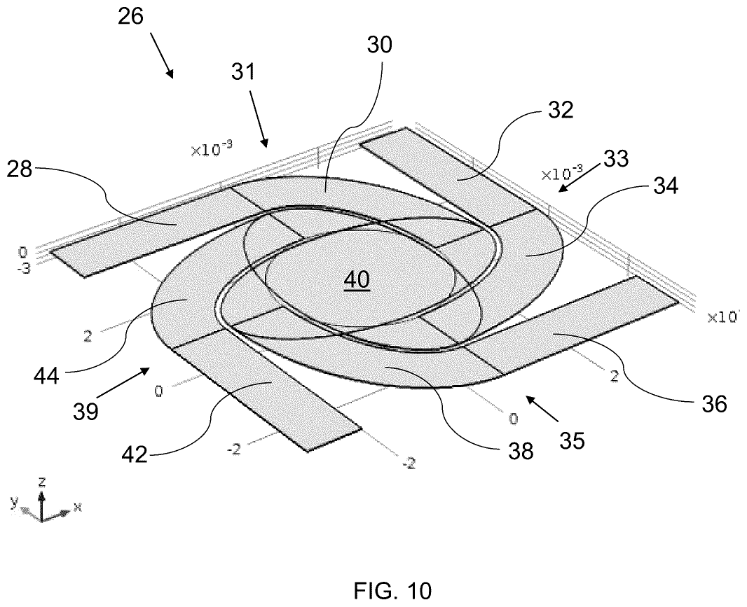

As shown in FIGS. 10-11, the central moveable element 40 can be stiffened, for example, by having a large mass 46 disposed below the moveable element 40. Increased stiffness prevents the moveable element 40 from deforming upon actuation of the surrounding actuator arms 31, 33, 35, 39. However, the applicant has envisioned scenarios in which it is desirable for the central moveable element to be deformable.

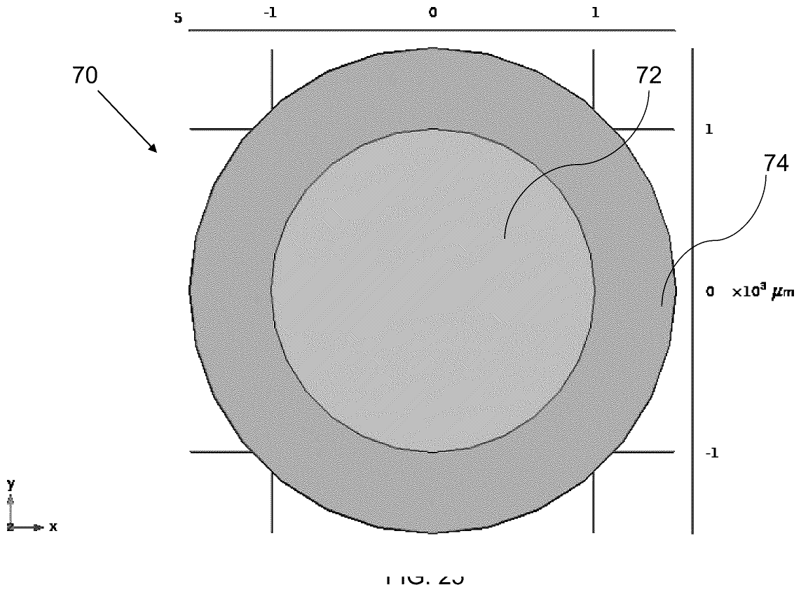

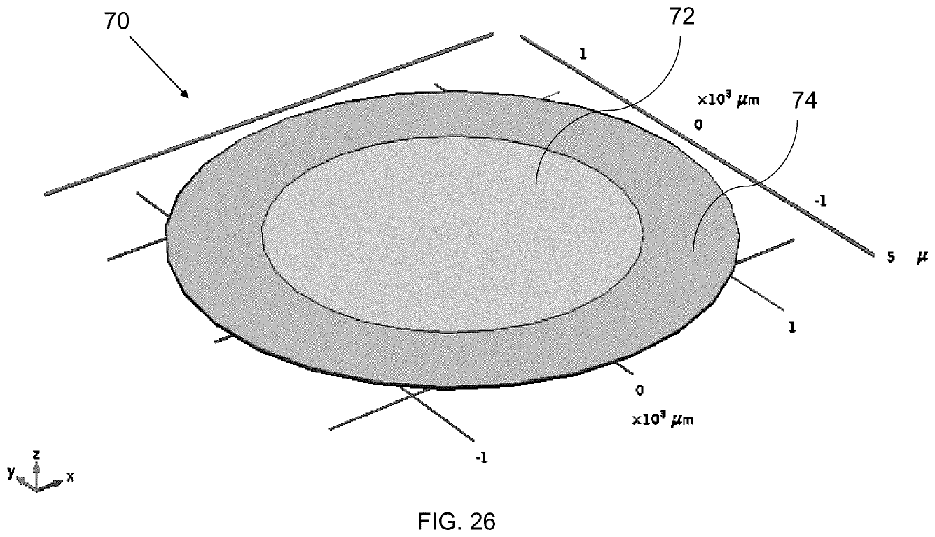

FIG. 25 shows a plan view of a deformable element 70, which is a variant of the central moveable element 4, 40, 68 shown in the foregoing embodiments. The deformable element 70 has an overall diameter of approximately 3 mm. The deformable element 70 of FIG. 25 has two independently actuable sections. The first section 72 is a central circular section and the second section 74 has the shape of an annulus arranged concentrically around the central circular section 72. The first section has a diameter of approximately 2 mm. Although only two sections are shown, there may be more concentrically arranged sections (e.g. further annuli) surrounding the central section. FIG. 26 shows a perspective view of the deformable element 70.

A voltage can be applied independently to each section of the deformable element using a control system similar to that shown in FIG. 21. For example, the control system could be the same as that shown in FIG. 21 having additional connections to the actuable sections 72, 74 on the central moveable element for providing additional control signals. The deformable element may be used as the central moveable surface in any actuating device embodying the invention, to provide focussing and de-focussing capability. Therefore, in cases where the deformable element has only two independently actuable sections, only two additional control signals would be necessary. If the deformable element were to have further, e.g. concentric, sections then a corresponding number of additional control signals would be necessary to actuate said sections.

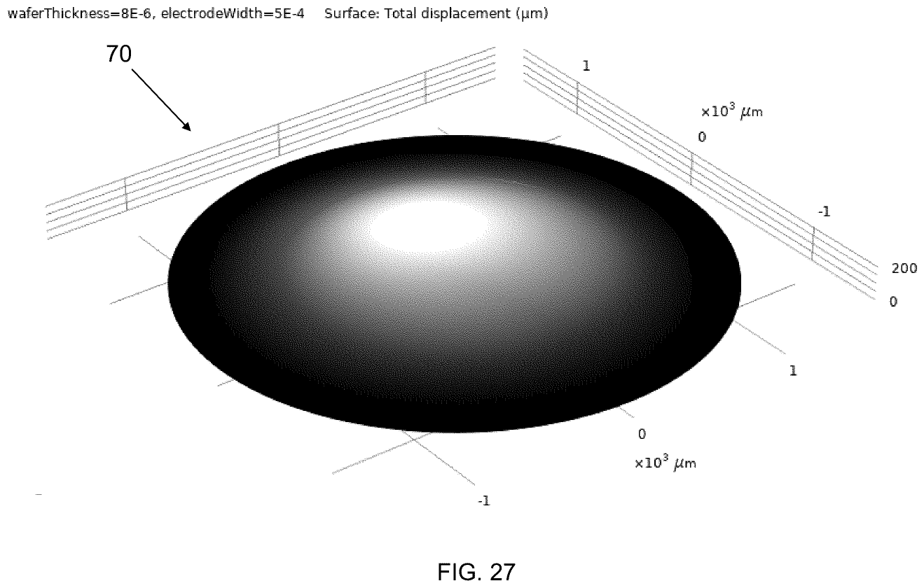

FIG. 27 is a perspective view showing the deformable element of FIG. 26 upon actuation. The shading in FIG. 27 illustrates the variation in vertical displacement, i.e. lift (in the z direction), of the surface. Minimal vertical displacement is shown in black and maximal vertical displacement is shown in white. Intermediate vertical displacements are represented by shades of grey. In contrast to the stiff central moveable elements (e.g. 4, 40) described above, which are attached to a large mass, the deformable element 70 is relatively thin and has the same thickness as the actuator arms. This thin deformable central element makes the entire actuating device thinner (e.g. having a thickness of between 10-100 μm) and may reduce the space required by such a device. The deformable central element having the same thickness as the actuator arms may also reduce the complexity of manufacturing the actuating device and therefore may lower manufacturing costs. Furthermore, the ability to focus and defocus light may remove the need for focussing optics, thus reducing the overall size of the device.

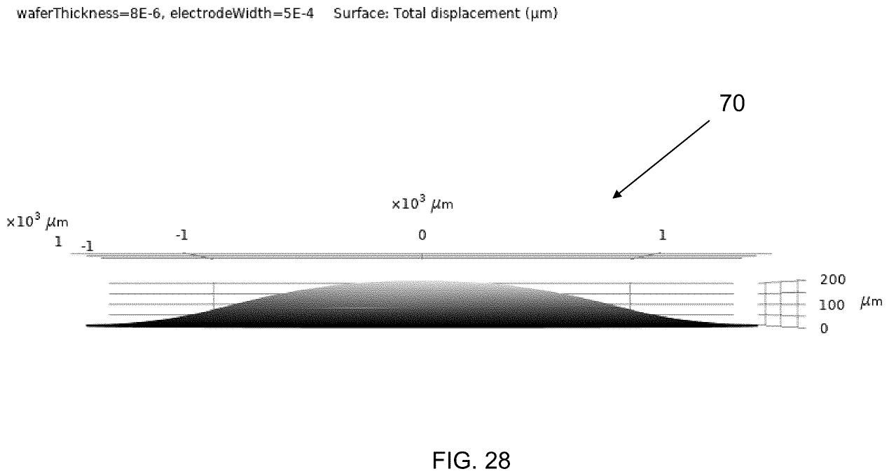

FIG. 28 is a side view of the actuated deformable element shown in FIG. 27. The deformable element, comprises a curved surface with minimal vertical displacement around the perimeter of the element and maximal vertical displacement at the centre of the deformable element. FIG. 28 shows that the vertical displacement of the deformable element can reach 200 μm for a diameter of between 2-3 mm.

The deformable element of FIGS. 25-28 is also optically reflective. This provides a deformable mirror element in the centre of the actuating device which can give the actuating device the ability to focus and defocus incident light.

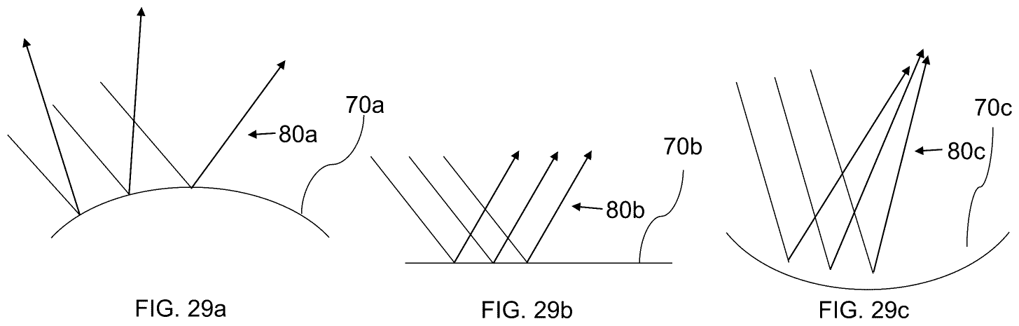

FIG. 29 (a)-(c) shows how the changing curvature of an optically reflective central moveable element changes the way light is deflected by the actuating device. When the deformable element 70 has an optically reflective surface, it can act as a focussing or defocussing mirror, depending on how it is deformed.

As illustrated in FIGS. 27-28 the first section 72 and the second section 74 may be actuated with a different voltage to cause at least part of the surface of the deformable element 70 to be displaced in the z direction. Applying a voltage to just the central section 72 of the deformable element 70 may result in a concave deformation of the deformable element 70. Applying a voltage to just the outer ring section 74 of the deformable element 70 may result in the opposite convex deformation. Having the deformable element 70, segmented in this way, may allow deformation of the deformable element 70 in both directions, upwards and downwards (e.g. in a convex or concave manner). In this example, a voltage is applied to only one of the sections and the centre of the deformable element is lifted the most from its rest position. This gives the deformable element the curved profile shown in FIG. 28. If a light source is arranged to illuminate the uppermost surface of the deformable element 70 shown in FIGS. 27-28, then the light from the light source will be incident on the convex surface of the deformable element. If that same surface is optically reflective, e.g. having a mirrored coating, then the light will be reflected with a divergence angle depending on the curvature of the deformable element 70.

A schematic version of a convex deformable element 70a is shown in FIG. 29a. The convex optically reflective surface causes the divergence angle of the reflected light 80a to be greater than the divergence angle of the incident light and thus the incoming light is de-focussed. A schematic version of a planar deformable element 70b is shown in FIG. 29b. The planar optically reflective surface causes the divergence angle of the reflected light 80b to be the same as the divergence angle of the incident light and so the surface provides specular reflection. A schematic version of a concave deformable element 70c is shown in FIG. 29c. The concave optically reflective surface causes the divergence angle of the reflected light 80c to be less than the divergence angle of the incident light and to the incoming light is focussed.

The foregoing embodiments describe various potential architectures for the actuating device in accordance with the invention. The applicant has realised that there are a number of ways that the benefits provided by the actuating device can be exploited. For instance, actuating devices having an optically reflective surface are especially useful in the fields of optics, imaging and projection.

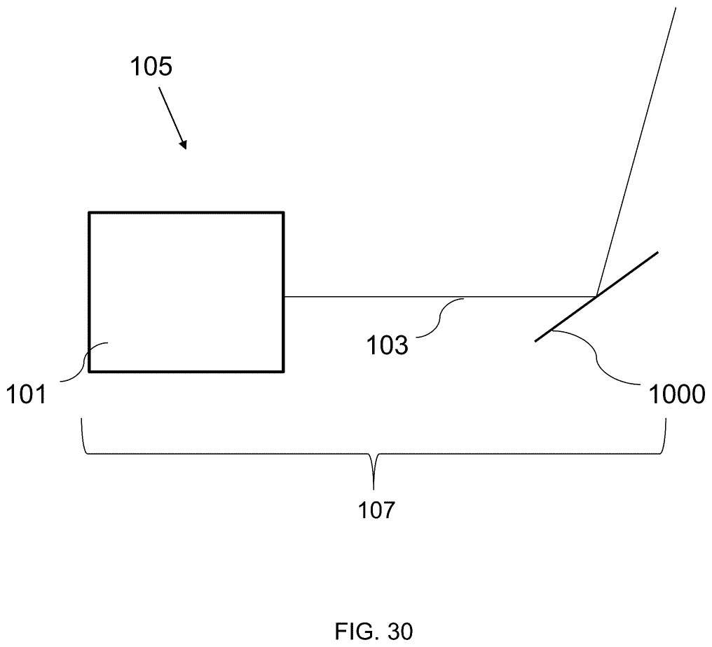

One example of a system that benefits from incorporating the actuating device according to the foregoing embodiments is a projector system 105, shown schematically in FIG. 30. FIG. 30 shows a projector unit 107 comprising an actuating device 1000 in accordance with the present invention—e.g. according to one of the embodiments described above. The projector unit 107 comprises a projector 101, (e.g. an LED projector or a laser beam projector which pairs a laser beam source with a fast moving mirror such as a resonant oscillating mirror) and the actuating device 1000. In alternative embodiments, the projector unit 107 could be an imaging unit and the projector 101 could be replaced with a camera to provide an imaging system. Such an imaging system could be used for gesture detection. In some other examples, the projector 101 may be used alongside a camera enabling both projection and image capture. The camera and projector may use a common actuating device 1000 (if they want to ‘see’ and project around the same area) or use separate actuating devices. In such dual-purpose systems, a person may interact with the projected light, e.g. via gestures, or the visible light projected may be adjusted based on what could be seen in the camera.

The projector 101 and actuating device 1000 of the projector unit 107 may be located within a common housing. Equally, they may be separate, in separate housings.

The actuating device 1000 could be provided by any actuating device embodying the invention including any of the embodiments described herein—e.g. the spiral design 26, one-armed design 2, etc.

The central moveable element of the actuating device 1000 has an optically reflecting surface to allow it to function as a moveable mirror 1000.

Although this projector system 105 could be used with any particular wavelength of light, in FIG. 30 the projector 101 is arranged to output visible light 103 to be projected by the projector system and the moveable mirror 1000 is arranged to reflect visible light 103 to direct it to a target.

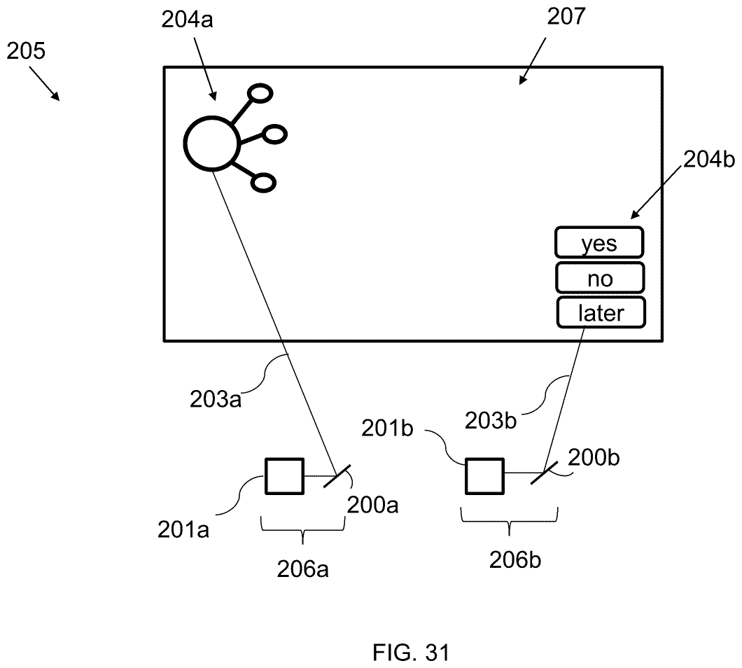

FIG. 31 shows a first example of the projector system 205 shown in FIG. 30. In the example projector system 205 there are two projector units 207a, 207b. The projector units 207a and 207b are arranged to project an image onto a surface 206. The projected images 204a and 204b together represent a total user interface. The user interface may be projected onto a table and may receive user input via gestures or voice recognition. For example, there is an image of an option menu 204b providing options (yes, no, later) for the user to select with gestures or voice or by another mechanism. Using the high deflection actuating devices 200a, 200b, the resolution is not constant over whole area 206 but instead, high resolution is provided only where it needs to be, i.e. in the areas where each image is projected 204a, 204b.

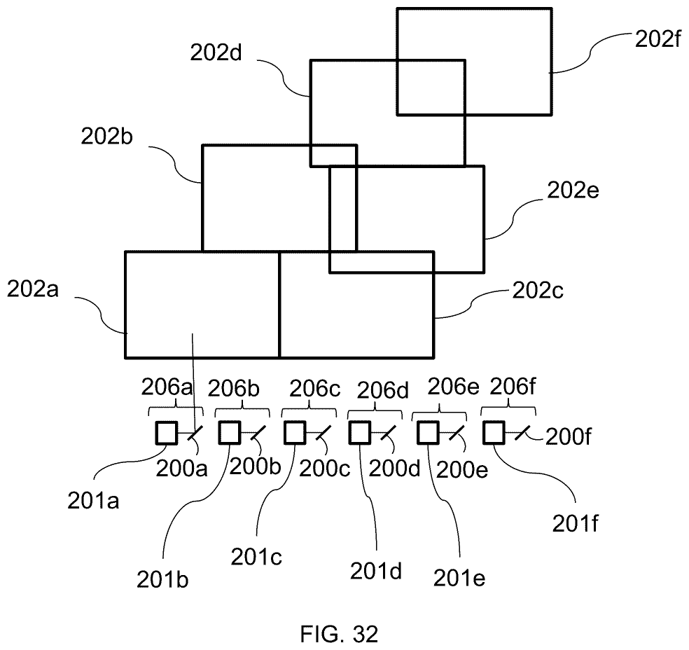

FIG. 32 shows a second example of a projector system. An illustration of a scene showing a meandering river is displayed (e.g. on a wall) by combining multiple projector units 207a, . . . 207n each displaying a scene component 202a, . . . 202n. The first projector unit 207a projects the first scene component 202a, the second projector unit 207b projects the second scene component 202b and so on. The projection works and is most suitable when there is not full or dense information to be displayed all over the surface—i.e. when it is not necessary to render the image everywhere in the field of view at the same time. In these situations, power and cost can be saved by using an array of smaller components to generate a rich high resolution image that has blank or unused areas.

It will be appreciated by those skilled in the art that the invention has been illustrated by describing one or more specific embodiments thereof, but is not limited to these embodiments; many variations and modifications are possible, within the scope of the accompanying claims.

1. An actuating device comprising:
at least one actuator arm comprising a piezoelectric membrane and having a width at least ten times its thickness; and
a moveable element, connected to the actuator arm, such that actuation of the actuator arm causes movement of the moveable element.

2. The actuating device of claim 1, wherein the actuator arm comprises a plurality of independently addressable piezoelectric segments.

3. The actuating device of any preceding claim, comprising a gap between at least part of the actuator arm and the moveable element.

4. The actuating device of any preceding claim, comprising a single actuator arm extending at least partially around a perimeter of the moveable element.

5. The actuating device of claim 4, wherein the actuator arm extends at least half-way around said perimeter of the moveable element.

6. The actuating device of any of claims 1 to 3, wherein the device comprises a plurality of actuator arms each connected to the moveable element.

7. The actuating device of claim 6, wherein each actuator arm comprises a plurality of independently addressable piezoelectric segments, and wherein the actuator arms and segments thereof are arranged such that the moveable element is tilted by selectively actuating the segments on one side of the moveable element.

8. The actuating device of claim 7, wherein the actuator arms and segments thereof are arranged such that the moveable element is translated in a direction normal to the plane of the piezoelectric membrane by selectively actuating the segments either closest to or furthest from the moveable element respectively.

9. The actuating device of any preceding claim, wherein the moveable element comprises an optically reflective surface.

10. The actuating device of claim 9, wherein the optically reflective surface has an aperture size between 0.1 mm and 50 mm.

11. The actuating device of any preceding claim, wherein the or each actuator arm has a constant width along its length.

12. The actuating device of any preceding claim, wherein the or each actuator arm is connected to the moveable element via a connecting member having a thickness greater than the thickness of the or each actuator arm.

13. The actuating device of any preceding claim, wherein the mass per unit area of the moveable element is greater than that of the actuator arm(s).

14. The actuating device of any preceding claim, wherein the moveable element comprises a plurality of individually addressable piezoelectric sections so that the moveable element is a deformable moveable element which can change shape on actuation.

15. The actuating device of claim 14, wherein the deformable moveable element has a thickness within 25% of the thickness of the actuator arm(s).

16. The actuating device of claim 14 or 15, wherein the deformable moveable element comprises a first individually addressable piezoelectric section and a second individually addressable piezoelectric section, and wherein the first section is circular and the second section is an annulus surrounding the first section.

17. The actuating device of any of claims 14 to 16, wherein the deformable moveable element has an upper surface and a lower surface, and wherein both the upper surface and lower surface have an optically reflective surface.

18. The actuating device of any preceding claim, wherein the membrane comprises a piezoelectric layer and a second layer.

19. The actuating device of claim 18, wherein the piezoelectric layer is at least 90% of the width of the actuator arm.

20. A projection system comprising:
a projector; and
the actuating device of any preceding claim, wherein the moveable element of the actuating device is optically reflective.

21. An imaging system comprising:
a camera; and
the actuating device of any preceding claim, wherein the moveable element of the actuating device is optically reflective.

22. An imaging and projecting system comprising:
a camera;
a projector; and
an actuating device according to any preceding claim, wherein the moveable element of the actuating device is optically reflective; and wherein the actuating device is shared by the camera and the projector.
